(19) United States
(12) Patent Application Publication
(10) Pub. No.: US 2024/0413071 A1
(43) Pub. Date: Dec. 12, 2024

(54) SEMICONDUCTOR PACKAGE AND PACKAGE MODULE INCLUDING THE SAME

(71) Applicant: SAMSUNG ELECTRONICS CO., LTD., Suwon-si (KR)

(72) Inventors: Narae SHIN, Suwon-si (KR); Jeong-Kyu HA, Suwon-si (KR)

(73) Assignee: SAMSUNG ELECTRONICS CO., LTD., Suwon-si (KR)

(21) Appl. No.: 18/623,666

(22) Filed: Apr. 1, 2024

(30) Foreign Application Priority Data
Jun. 8, 2023 (KR) 10-2023-0073699

(51) Int. Cl. H01L 23/498; H01L 23/00

(52) U.S. Cl. CPC H01L 23/49838; H01L 23/49822; H01L 23/4985; H01L 24/16; H01L 24/32; H01L 24/73; H01L 2224/16227; H01L 2224/32225; H01L 2224/73204

(57) ABSTRACT

Provided is a semiconductor package including a film substrate including a sprocket hole, a semiconductor chip on the film substrate, interconnection lines connected to the semiconductor chip, a dummy pattern between the sprocket hole and the semiconductor chip, and a cutting pattern between the semiconductor chip and the dummy pattern, wherein the cutting pattern is spaced apart from the interconnection lines and the dummy pattern in a first direction.

### CROSS-REFERENCE TO RELATED APPLICATIONS

This U.S. non-provisional patent application claims priority to Korean Patent Application No. 10-2023-0073699, filed on Jun. 8, 2023, in the Korean Intellectual Property Office, the disclosure of which is incorporated herein in its entirety by reference.

### BACKGROUND

Embodiments of the present disclosure relate to a semiconductor package, and more particularly, to a semiconductor package including a cutting pattern, and a package module including the same.

A chip-on-film (COF) package technique using a flexible film substrate has been developed to provide relatively small, thin and light electronic products. According to the COF package technique, a semiconductor chip may be mounted on the substrate by a flip-chip bonding method and may be electrically connected to an external circuit through short lead lines. COF packages realized by this technique may be applied to portable devices (e.g., a cellular phone or a personal digital assistant (PDA)), laptop computers, and panels of display devices.

### SUMMARY

One or more embodiments provide a semiconductor package capable of inhibiting or preventing a film substrate from being crumpled or bent, and a package module including the same.

According to an aspect of an embodiment, there is provided a semiconductor package including a film substrate including a sprocket hole, a semiconductor chip on the film substrate, interconnection lines connected to the semiconductor chip, a dummy pattern between the sprocket hole and the semiconductor chip, and a cutting pattern between the semiconductor chip and the dummy pattern, wherein the cutting pattern is spaced apart from the interconnection lines and the dummy pattern in a first direction.

According to another aspect of an embodiment, there is provided a semiconductor package including a film substrate, a semiconductor chip on the film substrate, interconnection lines connected to the semiconductor chip, and a cutting pattern on the film substrate and spaced apart from the interconnection lines in a first direction, wherein a side surface of the cutting pattern is coplanar with a side surface of the film substrate, and wherein the interconnection lines and the cutting pattern include same material.

According to another aspect of an embodiment, there is provided a package module including a circuit substrate, a display panel spaced apart from the circuit substrate in a first direction, and a plurality of semiconductor packages between the circuit substrate and the display panel, and electrically connecting the circuit substrate and the display panel, wherein each of the semiconductor packages includes a film substrate, a connecting portion connected to the display panel, a first connection pad connected to the circuit substrate, a semiconductor chip on the film substrate, interconnection lines connected to the semiconductor chip, an interconnection protective layer on the interconnection lines, and a cutting pattern on the film substrate and spaced apart from the semiconductor chip, the display panel, and the circuit substrate, wherein the semiconductor chip includes a first output pad connected to the connecting portion, and a second output pad connected to the first connection pad, wherein the interconnection lines include a first interconnection line connecting the connecting portion to the first output pad, and a second interconnection line connecting the first connection pad to the second output pad, and wherein the connecting portion, the first connection pad, the interconnection lines, and the cutting pattern include material.

### BRIEF DESCRIPTION OF THE DRAWINGS

Embodiments will be more clearly understood from the following detailed description taken in conjunction with the accompanying drawings in which:

FIG. 1A is a plan view illustrating a semiconductor package according to some embodiments;

FIG. 1B is a cross-sectional view taken along a line A-A′ of FIG. 1A;

FIG. 2 is a plan view illustrating a semiconductor package according to some embodiments;

FIG. 3 is a plan view illustrating a semiconductor package according to some embodiments;

FIG. 4 is a plan view illustrating a semiconductor package according to some embodiments;

FIG. 5 is a cross-sectional view illustrating a semiconductor package according to some embodiments;

FIG. 6 is a plan view illustrating a semiconductor package according to some embodiments;

FIG. 7A is a plan view illustrating a semiconductor package according to some embodiments;

FIG. 7B is a cross-sectional view taken along a line B-B′ of FIG. 7A;

FIG. 7C is a plan view illustrating a package module according to some embodiments;

FIGS. 8A, 8B and 8C are cross-sectional views illustrating a method of manufacturing a semiconductor package according to some embodiments.

### DETAILED DESCRIPTION

Embodiments will now be described more fully with reference to the accompanying drawings. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

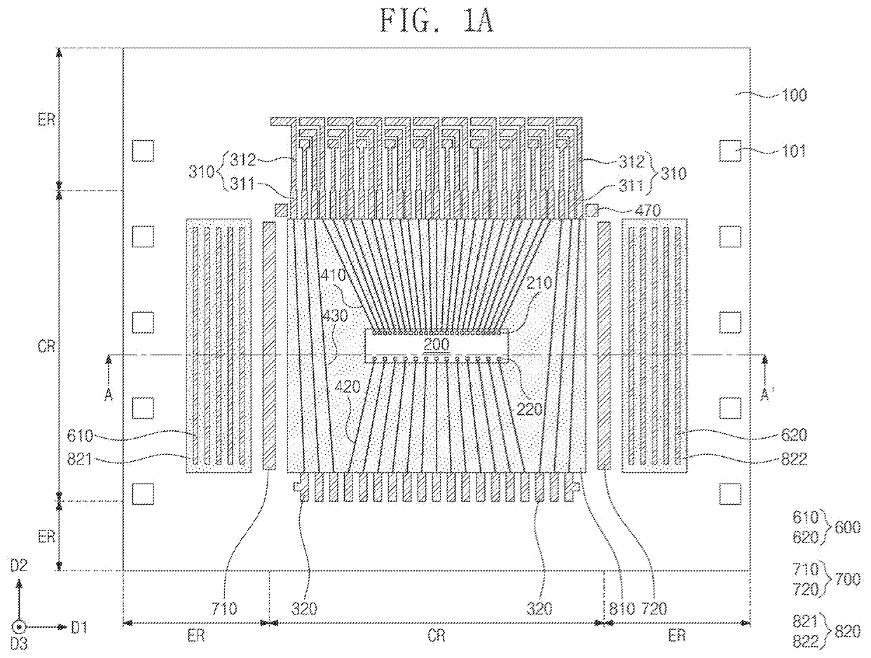

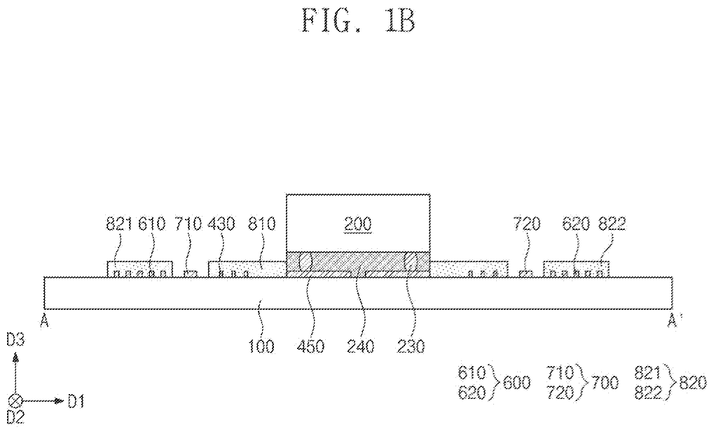

FIG. 1A is a plan view illustrating a semiconductor package according to some embodiments. FIG. 1B is a cross-sectional view taken along a line A-A′ of FIG. 1A.

Referring to FIGS. 1A and 1B, a semiconductor package may include a film substrate 100, a semiconductor chip 200, first connection pads 310, second connection pads 320, first interconnection lines 410, second interconnection lines 420, third interconnection lines 430, a dummy pattern 600, a cutting pattern 700, an interconnection protective layer 810, and a dummy protective layer 820.

The film substrate 100 may be a base film on which the semiconductor chip 200, the first connection pads 310, the second connection pads 320, the first to third interconnection lines 410, 420 and 430, the dummy pattern 600, the cutting pattern 700, the interconnection protective layer 810 and the dummy protective layer 820 are provided. The film substrate 100 may have a plate shape extending in a plane extending in a first direction D1 and a second direction D2. The first direction D1 and the second direction D2 may intersect each other. For example, the first direction D1 and the second direction D2 may be horizontal directions perpendicular to each other. The film substrate 100 may include a polymer material. For example, the film substrate 100 may include polyimide. The film substrate 100 may be a flexible substrate. The film substrate 100 may be bendable. The film substrate 100 may include a chip region CR and an edge region ER. For example, the chip region CR may be a region on which the semiconductor chip 200 is mounted, and the edge region ER may be a region adjacent to and surrounding the chip region CR in a plan view.

The film substrate 100 may include a plurality of sprocket holes 101. The sprocket holes 101 may be disposed in the edge region ER of the film substrate 100 when viewed in a plan view. The sprocket holes 101 may be arranged and spaced apart from each other in the second direction D2. The sprocket holes 101 may penetrate the film substrate 100. The semiconductor package may be wound or unwound using the sprocket holes 101.

The semiconductor chip 200 may be provided on the chip region CR of the film substrate 100. The semiconductor chip 200 may have a top surface and a bottom surface, which are opposite to each other. The semiconductor chip 200 may include first output pads 210 and second output pads 220, which are provided at the bottom surface of the semiconductor chip 200. The first output pads 210 may be spaced apart from each other in the first direction D1. The second output pads 220 may be spaced apart from each other in the first direction D1. The first output pads 210 and the second output pads 220 may include a conductive material. The first output pads 210 and the second output pads 220 may be connected to an integrated circuit of the semiconductor chip 200 to transmit output signals.

For example, the semiconductor chip 200 may be a display driving chip (i.e., a display driver IC) for driving a display panel. For example, the semiconductor chip 200 may generate image signals using data signals transmitted from a timing controller and may output the image signals to the display panel. In some embodiments, the semiconductor chip 200 may be the timing controller connected to the display driving chip.

The first connection pads 310 and the second connection pads 320 may be provided on the film substrate 100. The first connection pad 310 may include a connecting portion 311 and a cutting portion 312. The connecting portion 311 may be provided on the chip region CR of the film substrate 100. The cutting portion 312 may be provided on the edge region ER of the film substrate 100. The first connection pads 310 may be spaced apart from each other in the first direction D1. The second connection pads 320 may be provided on the chip region CR of the film substrate 100. The second connection pads 320 may be spaced apart from each other in the first direction D1. The first connection pads 310 and the second connection pads 320 may be spaced apart from each other in the second direction D2 with the semiconductor chip 200 interposed therebetween. The first connection pads 310 and the second connection pads 320 may include a conductive material. For example, the first connection pads 310 and the second connection pads 320 may include copper (Cu).

The first to third interconnection lines 410, 420 and 430 may be provided on the film substrate 100. The first to third interconnection lines 410, 420 and 430 may be spaced apart from each other.

The first interconnection line 410 may connect the first output pad 210 of the semiconductor chip 200 to the first connection pad 310. The first interconnection line 410 may electrically connect the semiconductor chip 200 to the connecting portion 311 of the first connection pad 310. The first interconnection lines 410 may be spaced apart from each other in the first direction D1. A distance between the first interconnection lines 410 may increase as a distance from the semiconductor chip 200 increases.

The second interconnection line 420 may connect the second output pad 220 of the semiconductor chip 200 to the second connection pad 320. The second interconnection line 420 may electrically connect the semiconductor chip 200 to the second connection pad 320. The second interconnection lines 420 may be spaced apart from each other in the first direction D1. A distance between the second interconnection lines 420 may increase as a distance from the semiconductor chip 200 increases.

The third interconnection line 430 may connect the first connection pad 310 to the second connection pad 320. The third interconnection line 430 may electrically connect the connecting portion 311 of the first connection pad 310 to the second connection pad 320. The third interconnection lines 430 may be spaced apart from each other in the first direction D1.

The first to third interconnection lines 410, 420 and 430 may include a conductive material. For example, the first to third interconnection lines 410, 420 and 430 may include copper (Cu). The first to third interconnection lines 410, 420 and 430 may have linear shapes. However, embodiments are not limited thereto, and in certain embodiments, the shapes of the first to third interconnection lines 410, 420 and 430 may be variously changed depending on the arrangement of the first and second connection pads 310 and 320, a size of the semiconductor chip 200 and the arrangement of the first and second output pads 210 and 220.

The semiconductor package may further include test pads 470, lead lines 450, connection terminals 230, and an underfill layer 240.

The test pads 470 may be provided on the chip region CR of the film substrate 100. The test pads 470 may be spaced apart from the first to third interconnection lines 410, 420 and 430, the first connection pad 310, the second connection pad 320 and the semiconductor chip 200. The test pads 470 may include a conductive material. For example, the test pads 470 may include copper (Cu). Characteristics of the semiconductor chip 200 may be tested using the test pads 470. For example, the characteristics of the semiconductor chip 200 may be tested using a measurement device including a probe pin. For example, the probe pins of the measurement device may come in contact with the test pads 470 to test the characteristics of the semiconductor chip 200.

The lead lines 450 may be provided on the chip region CR of the film substrate 100. The lead lines 450 may include the first interconnection lines 410 and the second interconnection lines 420. The lead line 450 may be a portion of the first interconnection line 410 or a portion of the second interconnection line 420. The lead lines 450 may be electrically connected to driving integrated circuits in the semiconductor chip 200 through the first output pads 210 and/or the second output pads 220.

In some embodiments, the lead lines 450 may be disposed on the top surface and the bottom surface of the film substrate 100. In this case, the semiconductor package may further include a conductive via penetrating the film substrate 100.

The connection terminals 230 may be disposed between the film substrate 100 and the semiconductor chip 200. The connection terminals 230 may be provided between the lead lines 450 and the first output pads 210 and between the lead lines 450 and the second output pads 220. The connection terminals 230 may be electrically connected to corresponding ones of the first interconnection lines 410 and the second interconnection lines 420. The semiconductor chip 200 may be electrically connected to the first and second interconnection lines 410 and 420 through the connection terminals 230. The connection terminals 230 may include a conductive material and may include at least one of, for example, gold, nickel, tin, or copper. Each of the connection terminals 230 may be at least one of a solder ball, a pillar, or a bump.

The underfill layer 240 may be provided on the film substrate 100. The underfill layer 240 may fill a gap region between the film substrate 100 and the semiconductor chip 200. The underfill layer 240 may seal or encapsulate the lead lines 450 and the connection terminals 230. The underfill layer 240 may protect the lead lines 450 and the connection terminals 230 from the outside and may prevent contact between the connection terminals 230. The underfill layer 240 may include an insulating material. For example, the underfill layer 240 may include an epoxy-based polymer. In some embodiments, the underfill layer 240 may cover a portion of a side surface of the semiconductor chip 200 and a portion of the interconnection protective layer 810.

The dummy pattern 600 may be provided on the edge region ER of the film substrate 100. The dummy pattern 600 may be disposed between the semiconductor chip 200 and the sprocket holes 101. The dummy pattern 600 may be disposed between the first to third interconnection lines 410, 420 and 430 and the sprocket holes 101. The dummy pattern 600 may extend in the second direction D2. A width of the dummy pattern 600 in the first direction D1 may be less than a length of the dummy pattern 600 in the second direction D2. The width of the dummy pattern 600 in the first direction D1 may be less than a width of the semiconductor chip 200 in the first direction D1. The length of the dummy pattern 600 in the second direction D2 may be greater than a length of the semiconductor chip 200 in the second direction D2.

The dummy pattern 600 may include a conductive material. For example, the dummy pattern 600 may include copper (Cu).

The dummy pattern 600 may include a plurality of first dummy patterns 610 and a plurality of second dummy patterns 620. The first dummy patterns 610 and the second dummy patterns 620 may be symmetrical with respect to the semiconductor chip 200 interposed therebetween. The first dummy patterns 610 may be spaced apart from each other in the first direction D1. The second dummy patterns 620 may be spaced apart from each other in the first direction D1.

The cutting pattern 700 may be provided on the chip region CR and the edge region ER of the film substrate 100. The cutting pattern 700 may be disposed between the semiconductor chip 200 and the dummy pattern 600. The cutting pattern 700 may be disposed between the dummy pattern 600 and the first to third interconnection lines 410, 420 and 430. The cutting pattern 700 may extend in the second direction D2. A width of the cutting pattern 700 in the first direction D1 may be less than a length of the cutting pattern 700 in the second direction D2. The width of the cutting pattern 700 in the first direction D1 may be less than the width of the semiconductor chip 200 in the first direction D1. The length of the cutting pattern 700 in the second direction D2 may be greater than the length of the semiconductor chip 200 in the second direction D2. A height of the cutting pattern 700 in a third direction D3 may be equal to a height of the dummy pattern 600 in the third direction D3 and heights of the first to third interconnection lines 410, 420 and 430 in the third direction D3. The cutting pattern 700 may be spaced apart from the first to third interconnection lines 410, 420 and 430 and the dummy pattern 600 in the first direction D1. The cutting pattern 700 may be spaced apart from the first and second connection pads 310 and 320 and the semiconductor chip 200. The cutting pattern 700 may be electrically separated from a signal circuit of the semiconductor chip 200. The cutting pattern 700 may be electrically floated.

The cutting pattern 700 may include a conductive material. For example, the cutting pattern 700 may include copper (Cu). The cutting pattern 700 may include the same material as the first and second connection pads 310 and 320, the first to third interconnection lines 410, 420 and 430, the test pads 470 and the dummy pattern 600. For example, the cutting pattern 700 may include the same metal as the first and second connection pads 310 and 320, the first to third interconnection lines 410, 420 and 430, the test pads 470 and the dummy pattern 600. For example, the cutting pattern 700, the first and second connection pads 310 and 320, the first to third interconnection lines 410, 420 and 430, the test pads 470 and the dummy pattern 600 may include copper (Cu).

The cutting pattern 700 may include a first cutting pattern 710 and a second cutting pattern 720. The first cutting pattern 710 and the second cutting pattern 720 may be disposed to be symmetrical with respect to the semiconductor chip 200 interposed therebetween. The first cutting pattern 710 may be disposed between the first dummy pattern 610 and the semiconductor chip 200. The first cutting pattern 710 may be disposed between the first dummy pattern 610 and the first to third interconnection lines 410, 420 and 430. The second cutting pattern 720 may be disposed between the second dummy pattern 620 and the semiconductor chip 200. The second cutting pattern 720 may be disposed between the second dummy pattern 620 and the first to third interconnection lines 410, 420 and 430.

The edge region ER of the film substrate 100 may be removed to form a package module to be described later. The removal of the edge region ER of the film substrate 100 may include cutting the cutting pattern 700 on a boundary between the edge region ER and the chip region CR, and removing a portion of the cutting pattern 700 which is on the edge region ER.

As the cutting pattern 700 is provided on the boundary between the chip region CR and the edge region ER when the edge region ER of the film substrate 100 is removed, bending of the film substrate 100 may be reduced or minimized. Thus, it is possible to inhibit or prevent the film substrate 100 from protruding and/or being crumpled or bent.

The interconnection protective layer 810 may be provided on the chip region CR of the film substrate 100. The interconnection protective layer 810 may be disposed on the first to third interconnection lines 410, 420 and 430. The interconnection protective layer 810 may cover the first to third interconnection lines 410, 420 and 430. The interconnection protective layer 810 may expose the first and second connection pads 310 and 320. The interconnection protective layer 810 may be spaced apart from the semiconductor chip 200. The interconnection protective layer 810 may include an insulating material. For example, the interconnection protective layer 810 may include a solder resist material. The interconnection protective layer 810 may protect the first to third interconnection lines 410, 420 and 430. For example, the interconnection protective layer 810 may prevent oxidation and/or electrical short of the first to third interconnection lines 410, 420 and 430 which may occur in a thermal treatment process.

The dummy protective layer 820 may be provided on the edge region ER of the film substrate 100. The dummy protective layer 820 may be disposed on the dummy pattern 600. The dummy protective layer 820 may cover the dummy pattern 600. The dummy protective layer 820 may include an insulating material. For example, the dummy protective layer 820 may include a solder resist material. The dummy pattern 600 and the dummy protective layer 820 may protect the film substrate 100. For example, the dummy pattern 600 and the dummy protective layer 820 may reduce crumpling or bending of the film substrate 100.

The dummy protective layer 820 may include a first dummy protective layer 821 and a second dummy protective layer 822. The first dummy protective layer 821 may be provided on the first dummy pattern 610. The first dummy protective layer 821 may cover the first dummy pattern 610. The second dummy protective layer 822 may be provided on the second dummy pattern 620. The second dummy protective layer 822 may cover the second dummy pattern 620. The first dummy protective layer 821 and the second dummy protective layer 822 may be disposed to be symmetrical with respect to the semiconductor chip 200 interposed therebetween. The first dummy protective layer 821 and the second dummy protective layer 822 may be spaced apart from the interconnection protective layer 810.

The cutting pattern 700 may be spaced apart from the interconnection protective layer 810 and the dummy protective layer 820. The first cutting pattern 710 may be disposed between the first dummy protective layer 821 and the interconnection protective layer 810. The second cutting pattern 720 may be disposed between the second dummy protective layer 822 and the interconnection protective layer 810.

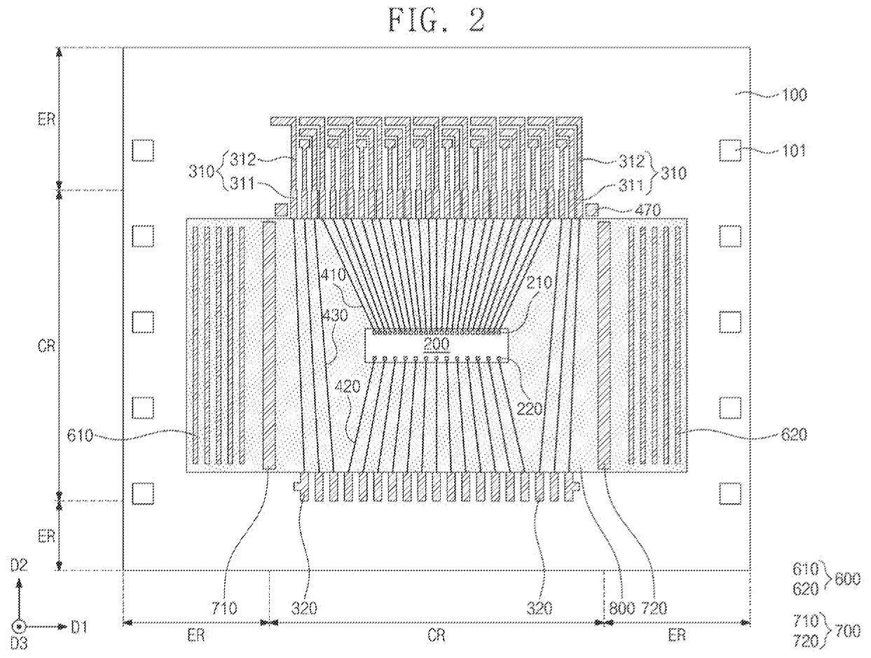

FIG. 2 is a plan view illustrating a semiconductor package according to some embodiments.

Referring to FIG. 2, a semiconductor package may include the film substrate 100, the semiconductor chip 200, the first connection pads 310, the second connection pads 320, the first to third interconnection lines 410, 420 and 430, the dummy pattern 600, the cutting pattern 700, and a protective layer 800.

The dummy pattern 600 may include a plurality of first dummy patterns 610 and a plurality of second dummy patterns 620. The cutting pattern 700 may include a first cutting pattern 710 and a second cutting pattern 720.

In the first direction D1, the protective layer 800 may be provided on the chip region CR and the edge region ER of the film substrate 100. In the second direction D2, the protective layer 800 may be provided on the chip region CR of the film substrate 100. The protective layer 800 may be provided on the first to third interconnection lines 410, 420 and 430, the plurality of first and second dummy patterns 610 and 620 and the first and second cutting patterns 710 and 720. The protective layer 800 may cover the first to third interconnection lines 410, 420 and 430, the plurality of first and second dummy patterns 610 and 620 and the first and second cutting patterns 710 and 720.

The protective layer 800 may expose the first and second connection pads 310 and 320. The protective layer 800 may be spaced apart from the semiconductor chip 200. The protective layer 800 may be disposed between the sprocket holes 101, arranged along the second direction D2 at each side of the edge region ER, in the first direction D1.

The protective layer 800 may protect the first to third interconnection lines 410, 420 and 430. For example, the protective layer 800 may prevent oxidation and/or electrical short of the first to third interconnection lines 410, 420 and 430 which may occur in a thermal treatment process. The protective layer 800 may protect the film substrate 100. For example, the protective layer 800 may prevent crumpling or bending of the film substrate 100.

The protective layer 800 may include an insulating material. For example, the protective layer 800 may include a solder resist material.

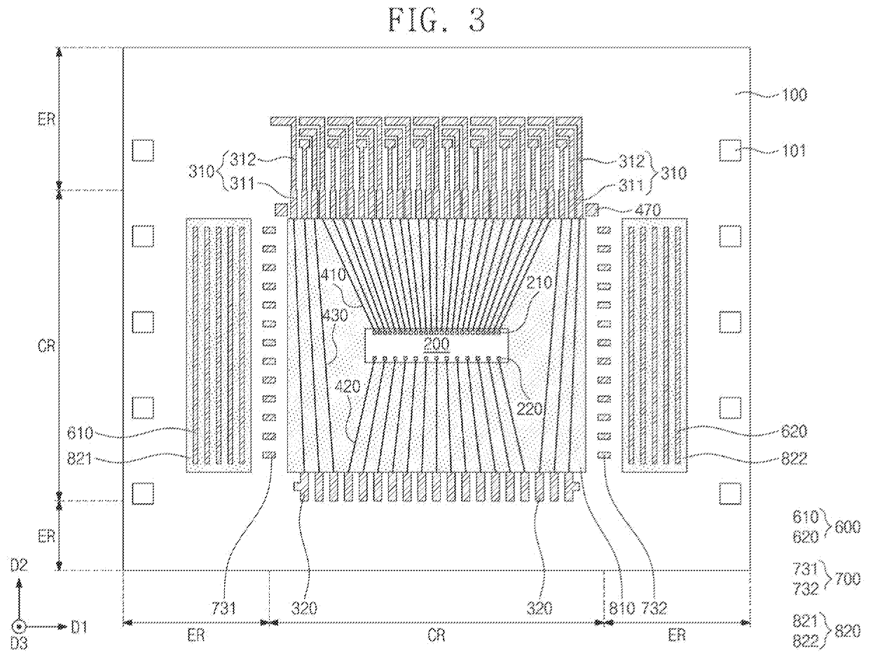

FIG. 3 is a plan view illustrating a semiconductor package according to some embodiments.

Referring to FIG. 3, a semiconductor package may include the film substrate 100, the semiconductor chip 200, the first connection pads 310, the second connection pads 320, the first to third interconnection lines 410, 420 and 430, the dummy pattern 600, a cutting pattern 700, the interconnection protective layer 810, and the dummy protective layer 820.

The dummy pattern 600 may include the plurality of first dummy patterns 610 and the plurality of second dummy patterns 620. The dummy protective layer 820 may include the first dummy protective layer 821 covering the first dummy patterns 610, and the second dummy protective layer 822 covering the second dummy patterns 620. The cutting pattern 700 may include a plurality of first small patterns 731 and a plurality of second small patterns 732.

The first small patterns 731 may be disposed between the first dummy patterns 610 and the semiconductor chip 200. The first small patterns 731 may be disposed between the first dummy protective layer 821 and the interconnection protective layer 810. The first small patterns 731 may be spaced apart from the first dummy protective layer 821 and the interconnection protective layer 810. The second small patterns 732 may be disposed between the second dummy patterns 620 and the semiconductor chip 200. The second small patterns 732 may be disposed between the second dummy protective layer 822 and the interconnection protective layer 810. The second small patterns 732 may be spaced apart from the second dummy protective layer 822 and the interconnection protective layer 810.

The first small patterns 731 may be spaced apart from each other and may be arranged in the second direction D2. The first small patterns 731 may be arranged in the second direction D2 at equal distances. The distance between the first small patterns 731 may be equal to or greater than a length of the first small pattern 731 in the second direction D2. A width of the first small pattern 731 in the first direction D1 may be greater than the length of the first small pattern 731 in the second direction D2.

The second small patterns 732 may be spaced apart from each other and may be arranged in the second direction D2. The second small patterns 732 may be arranged in the second direction D2 at equal distances. The distance between the second small patterns 732 may be equal to or greater than a length of the second small pattern 732 in the second direction D2. A width of the second small pattern 732 in the first direction D1 may be greater than the length of the second small pattern 732 in the second direction D2.

The first and second small patterns 731 and 732 may include a conductive material. For example, the first and second small patterns 731 and 732 may include copper

### (Cu).

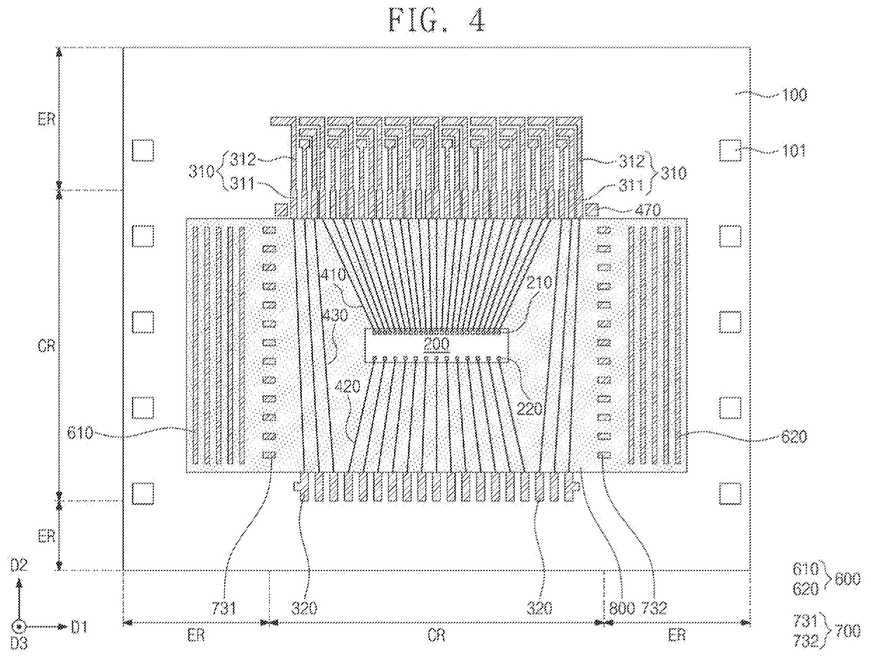

FIG. 4 is a plan view illustrating a semiconductor package according to some embodiments.

Referring to FIG. 4, a semiconductor package may include the film substrate 100, the semiconductor chip 200, the first connection pads 310, the second connection pads 320, the first to third interconnection lines 410, 420 and 430, the dummy pattern 600, the cutting pattern 700, and a protective layer 800.

The dummy pattern 600 may include the plurality of first dummy patterns 610 and the plurality of second dummy patterns 620. The cutting pattern 700 may include the plurality of first small patterns 731 and the plurality of second small patterns 732.

The protective layer 800 may be provided on the first to third interconnection lines 410, 420 and 430, the plurality of first and second dummy patterns 610 and 620 and the first and second small patterns 731 and 732. The protective layer 800 may cover the first to third interconnection lines 410, 420 and 430, the plurality of first and second dummy patterns 610 and 620 and the first and second small patterns 731 and 732.

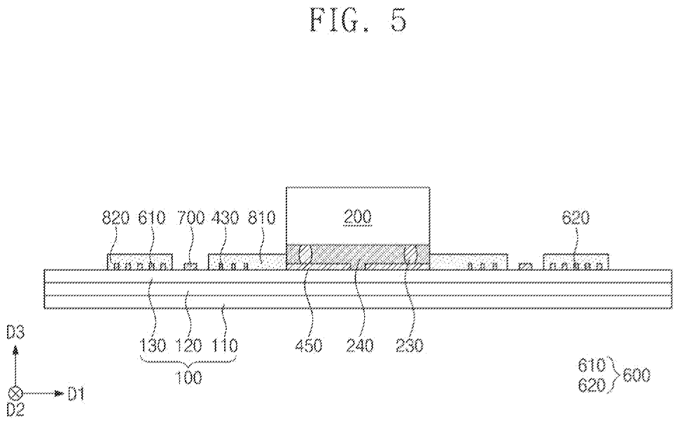

FIG. 5 is a cross-sectional view illustrating a semiconductor package according to some embodiments.

Referring to FIG. 5, a semiconductor package may include a film substrate 100, the semiconductor chip 200, the first connection pads 310, the second connection pads 320, the first to third interconnection lines 410, 420 and 430, the dummy pattern 600, the cutting pattern 700, the interconnection protective layer 810, and the dummy protective layer 820.

The film substrate 100 may include first to third substrates 110, 120 and 130. The second substrate 120 may be provided on the first substrate 110, and the third substrate 130 may be provided on the second substrate 120. The number of the substrates 110, 120 and 130 is not limited to the illustration of FIG. 5. According to embodiments, the number of the substrates 110, 120 and 130 may be two or less or may be four or more.

Each of the first to third substrates 110, 120 and 130 may include a plurality of sprocket holes.

The lead lines 450, the third interconnection lines 430, the dummy pattern 600, the cutting pattern 700, the interconnection protective layer 810 and the dummy protective layer 820 may be provided on the third substrate 130.

The first to third substrates 110, 120 and 130 may include a polymer material. For example, the first to third substrates 110, 120 and 130 may include polyimide.

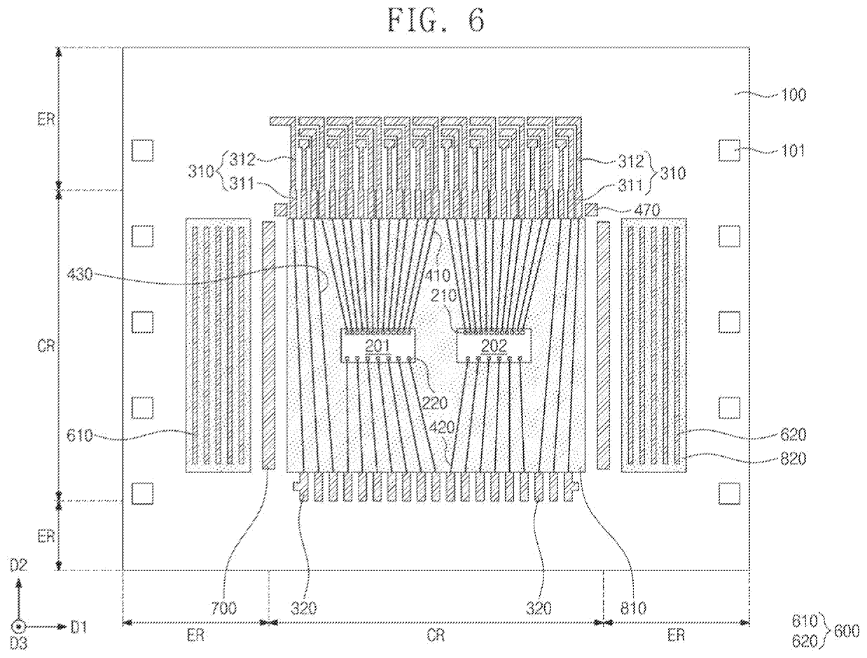

FIG. 6 is a plan view illustrating a semiconductor package according to some embodiments.

Referring to FIG. 6, a semiconductor package may include the film substrate 100, semiconductor chips 200, the first connection pads 310, the second connection pads 320, the first to third interconnection lines 410, 420 and 430, the dummy pattern 600, the cutting pattern 700, the interconnection protective layer 810, and the dummy protective layer 820.

The semiconductor chips 200 may include a first semiconductor chip 201 and a second semiconductor chip 202. Each of the first and second semiconductor chips 201 and 202 may have a top surface and a bottom surface, which are opposite to each other. Each of the bottom surfaces of the first and second semiconductor chips 201 and 202 may include first output pads 210 and second output pads 220. The first output pads 210 and the second output pads 220 may be connected to an integrated circuit of the first or second semiconductor chip 201 or 202 to transmit output signals.

The number of the semiconductor chips 201 and 202 is not limited to the illustration of FIG. 6. According to embodiments, the number of the semiconductor chips 201 and 202 may be three or more.

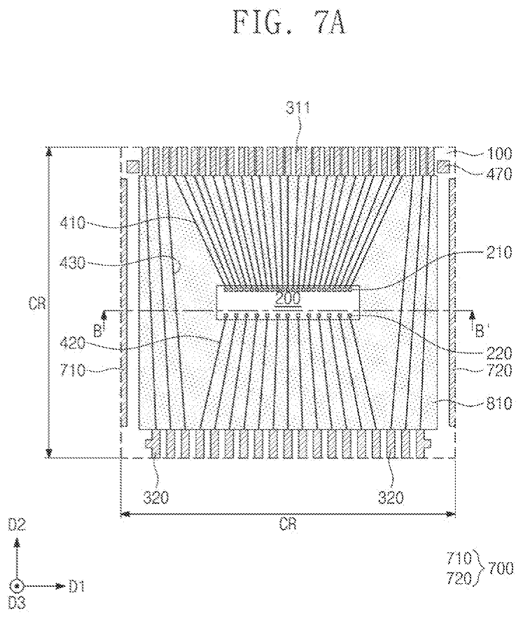

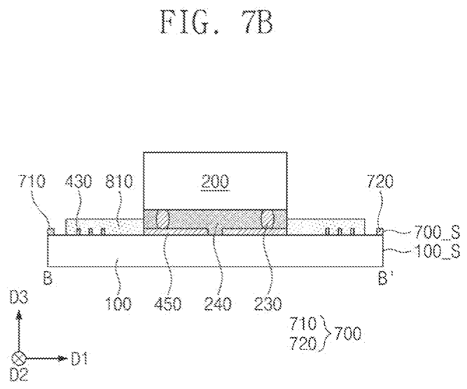

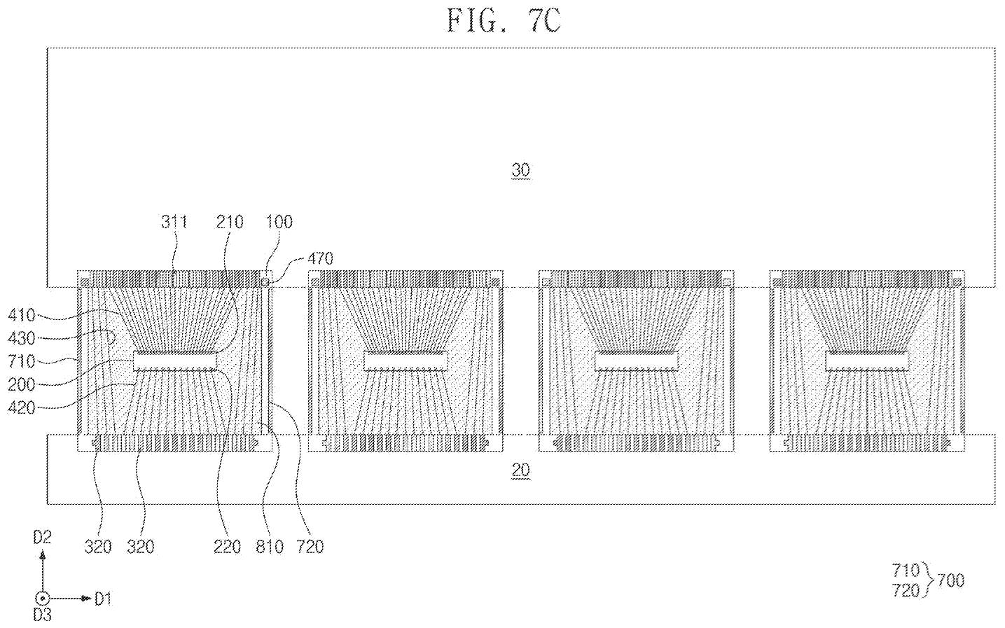

FIG. 7A is a plan view illustrating a semiconductor package according to some embodiments. FIG. 7B is a cross-sectional view taken along a line B-B′ of FIG. 7A. FIG. 7C is a plan view illustrating a package module according to some embodiments.

Referring to FIGS. 7A and 7B, the edge region ER of the film substrate 100 of the semiconductor package of FIG. 1A may be removed. The edge region ER of the film substrate 100 may be cut in a reel state and may be removed. When the edge region ER of the film substrate 100 is removed, the dummy pattern 600, the dummy protective layer 820, the cutting portions 312 and a portion of the cutting pattern 700 on the edge region ER may be removed.

The edge region ER of the film substrate 100 may be removed, and the chip region CR of the film substrate 100 may remain. The edge region ER of the film substrate 100 may be removed, and thus the semiconductor package may include the semiconductor chip 200, the connecting portions 311, the second connection pads 320, the first to third interconnection lines 410, 420 and 430, a portion of the cutting pattern 700 and the interconnection protective layer 810 on the chip region CR of the film substrate 100.

The interconnection protective layer 810 may cover the first to third interconnection lines 410, 420 and 430. The interconnection protective layer 810 may be spaced apart from the semiconductor chip 200.

The cutting pattern 700 may be spaced apart from the first to third interconnection lines 410, 420 and 430 and the interconnection protective layer 810. The cutting pattern 700 may extend in the second direction D2. A width of the cutting pattern 700 in the first direction D1 may be less than the length of the cutting pattern 700 in the second direction D2. The cutting pattern 700 may include the same material as the first to third interconnection lines 410, 420 and 430, the connecting portions 311 and the second connection pads 320. For example, the cutting pattern 700, the first to third interconnection lines 410, 420 and 430, the connecting portions 311 and the second connection pads 320 may include copper (Cu).

The cutting pattern 700 may include the first cutting pattern 710 and the second cutting pattern 720. The semiconductor chip 200 may be disposed between the first cutting pattern 710 and the second cutting pattern 720. The first to third interconnection lines 410, 420 and 430 may be disposed between the first cutting pattern 710 and the second cutting pattern 720.

A side surface 700_S of the cutting pattern 700 may be coplanar with a side surface 100_S of the film substrate 100.

According to embodiments, the semiconductor package may include the protective layer covering the cutting pattern 700, and a portion of the protective layer on the edge region ER may be removed when the edge region ER of the film substrate 100 is removed.

According to embodiments, the cutting pattern 700 may include a plurality of the small patterns, and portions of the small patterns on the edge region ER may be removed when the edge region ER of the film substrate 100 is removed.

Referring to FIG. 7C, a package module may include a plurality of semiconductor packages, a circuit substrate 20, and a display panel 30.

Each of the semiconductor packages may include the film substrate 100, the connecting portions 311, the second connection pads 320, the semiconductor chip 200 including the first output pads 210 and the second output pads 220, the first to third interconnection lines 410, 420 and 430, the interconnection protective layer 810, and the cutting pattern 700. The cutting pattern 700 may be spaced apart from the semiconductor chip 200, the display panel 30 and the circuit substrate 20 and may be electrically floated. The cutting pattern 700 may be spaced apart from the interconnection protective layer 810. According to embodiments, the cutting pattern 700 may be covered with the interconnection protective layer 810. The cutting pattern 700 may include the first cutting pattern 710 and the second cutting pattern 720. The first cutting pattern 710 and the second cutting pattern 720 may be disposed to be symmetrical with respect to the semiconductor chip 200 interposed therebetween. The cutting pattern 700 may include the same material as the connecting portion 311, the second connection pad 320 and the first to third interconnection lines 410, 420 and 430. For example, the cutting pattern 700, the connecting portion 311, the second connection pad 320 and the first to third interconnection lines 410, 420 and 430 may include copper (Cu).

The circuit substrate 20 may be disposed on the top surface of the film substrate 100. The circuit substrate 20 may be adjacent to a first side of the film substrate 100. For example, the circuit substrate 20 may be a printed circuit board (PCB) or a flexible printed circuit board (FPCB). Input connecting portions may be disposed between the second connection pads 320 and the circuit substrate 20 to electrically connect the second connection pads 320 to the circuit substrate 20. The circuit substrate 20 may be electrically connected to the semiconductor chip 200 through the second connection pads 320 and the second interconnection lines 420.

The display panel 30 may be disposed on the top surface of the film substrate 100. The display panel 30 may be adjacent to a second side of the film substrate 100 opposite to the first side of the film substrate 100. Output connecting portions may be disposed between the connecting portions 311 and the display panel 30 to electrically connect the connecting portions 311 to the display panel 30. The display panel 30 may be electrically connected to the semiconductor chip 200 through the connecting portions 311 and the first interconnection lines 410.

The semiconductor chip 200 may be supplied with signals from the circuit substrate 20 through the second connection pads 320 and the second interconnection lines 420. The semiconductor chip 200 may include driving integrated circuits (e.g., a gate driving integrated circuit and/or a data driving integrated circuit) and may generate driving signals (e.g., gate driving signals and/or data driving signals). The driving signals generated from the semiconductor chip 200 may be supplied to gate lines and/or data lines of the display panel 30 through the connecting portions 311 and the first interconnection lines 410. Thus, the display panel 30 may be driven.

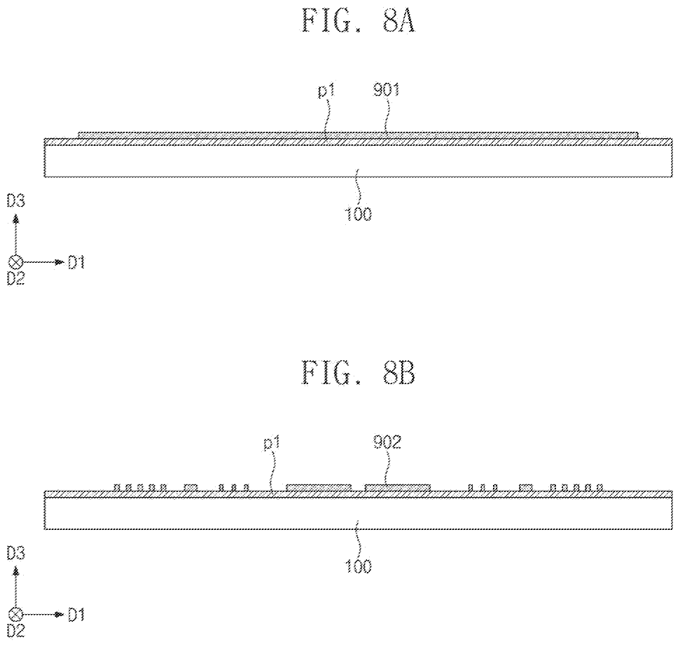

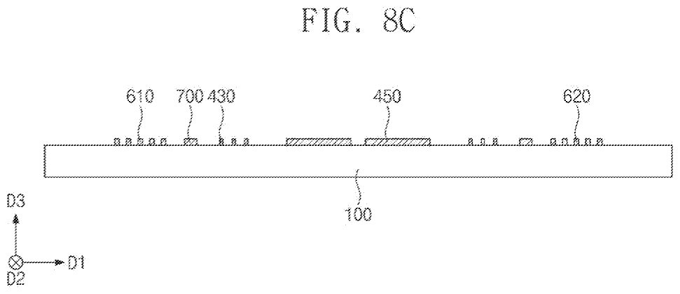

FIGS. 8A, 8B and 8C are cross-sectional views illustrating a method of manufacturing a semiconductor package according to some embodiments.

Referring to FIG. 8A, a film substrate 100 may be provided. A preliminary interconnection layer p1 may be formed to cover a top surface of the film substrate 100. A photoresist layer 901 may be formed to cover a portion of the preliminary interconnection layer p1.

Referring to FIG. 8B, portions of the photoresist layer 901 may be removed by a photolithography process to form a mask pattern 902 exposing portions of the preliminary interconnection layer p1. The mask pattern 902 may define regions in which first and second dummy patterns 610 and 620, first and second cutting patterns 710 and 720, first to third interconnection lines 410, 420 and 430 and lead lines 450 will be formed.

Referring to FIG. 8C, the exposed portions of the preliminary interconnection layer p1 may be removed. For example, the exposed portions of the preliminary interconnection layer p1 may be removed by an etching process. According to embodiments, the preliminary interconnection layer p1 may be etched using the mask pattern 902 as an etch mask. The exposed portions of the preliminary interconnection layer p1 may be removed to form first and second dummy patterns 610 and 620, first and second cutting patterns 710 and 720, first to third interconnection lines 410, 420 and 430 and lead lines 450.

Referring again to FIG. 1B, connection terminals 230 may be formed on the lead lines 450. An interconnection protective layer 810 and a dummy protective layer 820 may be formed on the top surface of the film substrate 100. The interconnection protective layer 810 may be formed on the first to third interconnection lines 410, 420 and 430, and the dummy protective layer 820 may be formed on the dummy pattern 600. For example, the formation of the interconnection protective layer 810 and the dummy protective layer 820 may be performed using a screen printing process or a spray coating process.

A semiconductor chip 200 may be mounted on the top surface of the film substrate 100. The mounting of the semiconductor chip 200 may include electrically connecting the first and second connection pads 310 and 320 to corresponding ones of the first to third interconnection lines 410, 420 and 430. An underfill layer 240 may be formed between the film substrate 100 and the semiconductor chip 200.

The semiconductor package according to the embodiments may include the cutting pattern provided on the chip region and the edge region of the film substrate, and thus the bending of the film substrate may be reduced or minimized when the film substrate is cut to remove the edge region.

While the embodiments have been particularly shown and described, it will be understood by one of ordinary skill in the art that variations in form and detail may be made therein without departing from the spirit and scope of the attached claims and their equivalents.

What is claimed is:

1. A semiconductor package comprising:
a film substrate comprising a sprocket hole;
a semiconductor chip on the film substrate;
interconnection lines connected to the semiconductor chip;
a dummy pattern between the sprocket hole and the semiconductor chip; and
a cutting pattern between the semiconductor chip and the dummy pattern,
wherein the cutting pattern is spaced apart from the interconnection lines and the dummy pattern in a first direction.

2. The semiconductor package of claim 1, further comprising:
an interconnection protective layer on the interconnection lines that are on the film substrate,
wherein the cutting pattern is spaced apart from the interconnection protective layer.

3. The semiconductor package of claim 2, further comprising:
a dummy protective layer on the dummy pattern,
wherein the cutting pattern is spaced apart from the dummy protective layer.

4. The semiconductor package of claim 1, further comprising:
a protective layer on the interconnection lines, the dummy pattern and the cutting pattern.

5. The semiconductor package of claim 1, wherein the cutting pattern comprises a plurality of small patterns, and
wherein each distance between adjacent small patterns of the plurality of small patterns is equal in a second direction intersecting the first direction.

6. The semiconductor package of claim 5, wherein the distance between the adjacent small patterns is equal to or greater than a length of each small pattern of the plurality of small patterns in the second direction.

7. The semiconductor package of claim 5, further comprising:
a protective layer on the interconnection lines, the dummy pattern and the small patterns.

8. The semiconductor package of claim 5, wherein a width of each small pattern of the plurality of small patterns in the first direction is greater than a length of each small pattern of the plurality of small patterns in the second direction.

9. The semiconductor package of claim 5, further comprising:
an interconnection protective layer on the interconnection lines; and
a dummy protective layer on the dummy pattern,
wherein the small patterns are spaced apart from the interconnection protective layer and the dummy protective layer.

10. The semiconductor package of claim 1, wherein a height of the cutting pattern in a third direction perpendicular to the first direction is equal to a height of the dummy pattern and a height of the interconnection lines in the third direction.

11. The semiconductor package of claim 1, wherein the semiconductor chip comprises a plurality of semiconductor chips.

12. The semiconductor package of claim 1, wherein the film substrate comprises a plurality of layers.

13. The semiconductor package of claim 1, wherein the dummy pattern comprises a plurality of first dummy patterns and a plurality of second dummy patterns, and
wherein the first dummy patterns and the second dummy patterns are symmetrical with respect to the semiconductor chip interposed therebetween.

14. A semiconductor package comprising:
a film substrate;
a semiconductor chip on the film substrate;
interconnection lines connected to the semiconductor chip; and
a cutting pattern on the film substrate and spaced apart from the interconnection lines in a first direction,
wherein a side surface of the cutting pattern is coplanar with a side surface of the film substrate, and
wherein the interconnection lines and the cutting pattern comprise same material.

15. The semiconductor package of claim 14, wherein a width of the cutting pattern in the first direction is less than a length of the cutting pattern in a second direction intersecting the first direction.

16. The semiconductor package of claim 14, further comprising:
an interconnection protective layer on the interconnection lines,
wherein the interconnection protective layer is spaced apart from the semiconductor chip.

17. The semiconductor package of claim 14, wherein the cutting pattern comprises a first cutting pattern and a second cutting pattern, and
wherein the semiconductor chip is between the first cutting pattern and the second cutting pattern.

18. A package module comprising:
a circuit substrate;
a display panel spaced apart from the circuit substrate in a first direction; and
a plurality of semiconductor packages between the circuit substrate and the display panel, and electrically connecting the circuit substrate and the display panel,
wherein each of the semiconductor packages comprises:
a film substrate;
a connecting portion connected to the display panel;
a first connection pad connected to the circuit substrate;
a semiconductor chip on the film substrate;
interconnection lines connected to the semiconductor chip;
an interconnection protective layer on the interconnection lines; and
a cutting pattern on the film substrate and spaced apart from the semiconductor chip, the display panel, and the circuit substrate,
wherein the semiconductor chip comprises a first output pad connected to the connecting portion, and a second output pad connected to the first connection pad,
wherein the interconnection lines comprise a first interconnection line connecting the connecting portion to the first output pad, and a second interconnection line connecting the first connection pad to the second output pad, and
wherein the connecting portion, the first connection pad, the interconnection lines, and the cutting pattern comprise material.

19. The package module of claim 18, wherein the cutting pattern is spaced apart from the interconnection protective layer.

20. The package module of claim 18, wherein the cutting pattern comprises a first cutting pattern and a second cutting pattern, and
wherein the first cutting pattern and the second cutting pattern are symmetrical with respect to the semiconductor chip interposed therebetween.
